(19) United States
(12) Patent Application Publication
(10) Pub. No.: US 2011/0168224 A1
(43) Pub. Date: Jul. 14, 2011

(54) THERMOELECTRIC DEVICE AND THERMOELECTRIC DEVICE ARRAY

(75) Inventor: Jin-woo CHO, Seongnam-si (KR)

(73) Assignee: SAMSUNG ELECTRONICS CO., LTD., Suwon-si (KR)

(21) Appl. No.: 12/907,078

(22) Filed: Oct. 19, 2010

(30) Foreign Application Priority Data
Jan. 14, 2010 (KR) 10-2010-0003563

(51) Int. Cl. H01L 35/28

(52) U.S. Cl. 136/212

(57) ABSTRACT

Disclosed is a thermoelectric device. The thermoelectric device may include a thermoelectric object disposed as a horizontal structure between a high-temperature region and a low-temperature region. Also, disclosed is a thermoelectric device array where a plurality of thermoelectric objects are disposed between the high-temperature region and the low-temperature region.

### CROSS-REFERENCE TO RELATED APPLICATIONS

This application claims the benefit of Korean Patent Application No. 10-2010-0003563, filed on Jan. 14, 2010, in the Korean Intellectual Property Office, the disclosure of which is incorporated herein in its entirety by reference.

### BACKGROUND

1. Field

Exemplary embodiments consistent with the present disclosure relate to a thermoelectric device, and more particularly, to a thermoelectric device and a thermoelectric device array in which a carrier moving direction or a heat flow direction in a thermoelectric object disposed between a high-temperature region and a low-temperature region is substantially parallel with surfaces facing the high-temperature region and the low-temperature region.

2. Description of the Related Art

A thermoelectric device refers to a device using the Seebeck effect phenomenon in which a temperature difference existing in the natural world and artifacts such as machinery or buildings produces an electromotive force based on thermoelectric conversion. Generally, in a thermoelectric device, as disclosed in U.S. Patent Publication No. 2009-25773, a heat flow direction or a carrier moving direction inside a thermoelectric object is perpendicular to surfaces facing a low-temperature region and a high-temperature region.

Thermoelectric conversion refers to conversion of thermal energy into electric energy or vice versa. Electricity is generated when a temperature difference is produced between both ends of a thermoelectric material. On the other hand, if a current is applied to the thermoelectric material, a temperature gradient is generated between both ends of the thermoelectric material.

Thermal energy produced in a computer or an automobile engine may be converted into electric energy by using the Seebeck effect, and various cooling systems may be implemented without a need for a refrigerant by using the Peltier effect. As interest in new energy development, waste energy recovery, environment protection, or the like is increasing, a thermoelectric device is also attracting much attention.

The efficiency of a thermoelectric device is determined by a figure of merit (ZT) coefficient, which is a performance coefficient of a thermoelectric material, and a non-dimensional performance parameter, where the ZT coefficient may be expressed as follows:

$$ZT = \frac{{S}^{2} σ}{k} T \qquad ( 1 )$$

In Equation (1), the ZT coefficient is proportional to a Seebeck coefficient S (volts/degree K) of the thermoelectric material and an electric conductivity σ (1/W-meter), and is inversely proportional to a thermal conductivity k (Watt/meter-degree K). The Seebeck coefficient S represents a voltage per unit temperature change (dV/dT), and T represents an absolute temperature.

To implement a high-efficiency thermoelectric device, the ZT coefficient has to be large. However, for the same material, the Seebeck coefficient S, the electric conductivity σ, and the thermal conductivity k have correlations among them, and thus they may not be controlled independently of one another. As a result, it is not easy to implement the high-efficiency thermoelectric device merely by improving the thermoelectric material.

### SUMMARY

Provided is a thermoelectric device capable of improving power efficiency by reducing contact thermal resistance in an electrode between a thermoelectric object and a high-temperature region and an electrode between the thermoelectric object and a low-temperature region and increasing a temperature gradient in the thermoelectric object.

Additional aspects will be set forth in part in the description which follows and, in part, will be apparent from the description, or may be learned by practice of the presented embodiment.

According to an aspect of the present disclosure, a thermoelectric device includes a low-temperature region, a high-temperature region, and a thermoelectric object formed between the low-temperature region and the high-temperature region, in which a direction of heat H or carriers moving in the thermoelectric object is substantially in parallel with facing surfaces of the low-temperature region and the high-temperature region.

An angle between the direction of heat H or carriers moving in the thermoelectric object and each of the facing surfaces of the low-temperature region and the high-temperature region may be less than about 45 degrees.

Thermoelectric object may be spaced apart from the low-temperature region and the high-temperature region, and include a first electrode formed between ends of the thermoelectric object and the low-temperature region and a second electrode formed between other ends of the thermoelectric object and the high-temperature region.

The thermoelectric device may further include an insulating layer formed between the end portion of the thermoelectric object and the low-temperature region or between the other ends of the thermoelectric object and the high-temperature region.

The facing surfaces may be surfaces on which the first electrode or the second electrode is formed.

The thermoelectric object may be formed in a direction perpendicular to a shortest line connecting the low-temperature region and the high-temperature region.

The thermoelectric object may include metal, intermetallic compounds, semiconductors, boride, or oxide.

The thermoelectric object may include an N-type material or a P-type material.

According to another aspect of the present disclosure, a thermoelectric device array includes a plurality of first electrodes formed on a low-temperature region, a plurality of second electrodes formed on a high-temperature region, and thermoelectric objects spaced apart from the low-temperature region and the high-temperature region and formed by connecting ends of the plurality of first electrodes and other ends of the plurality of second electrodes, in which a direction of heat H or carriers moving in the thermoelectric objects is substantially in parallel with facing surfaces of the low-temperature region and the high-temperature region.

The ends of the plurality of first electrodes and the other ends of the plurality of second electrodes may be reciprocally connected in turns by the thermoelectric objects, thus forming a zig-zag structure.

The thermoelectric objects may be formed such that an N-type thermoelectric object and a P-type thermoelectric object are formed in turns.

### BRIEF DESCRIPTION OF THE DRAWINGS

These and/or other aspects will become apparent and more readily appreciated from the following description of the exemplary embodiments, taken in conjunction with the accompanying drawings of which:

FIGS. 1A through 1C are views schematically illustrating a thermoelectric device according to an exemplary embodiment of the present disclosure;

FIGS. 2A and 2B are views illustrating a thermoelectric device array according to an exemplary embodiment of the present disclosure;

FIG. 3 is a view illustrating a thermoelectric module according to an exemplary embodiment of the present disclosure;

FIG. 4A is a view illustrating a thermoelectric device including a thermoelectric object formed perpendicular to facing surfaces of a high-temperature region and a low-temperature region;

FIG. 4B is a view illustrating a thermoelectric device including a thermoelectric object formed in parallel with facing surfaces of a high-temperature region and a low-temperature region, according to an exemplary embodiment of the present disclosure;

FIG. 5 is a view for describing a method of forming the thermoelectric device array shown in FIG. 2A, according to an exemplary embodiment of the present disclosure;

FIG. 6A is a view illustrating a thermoelectric device according to an exemplary embodiment of the present disclosure; and

FIG. 6B is a graph showing the result of analyzing a temperature distribution in a thermoelectric object of the thermoelectric device shown in FIG. 6A by using a numerical analysis program.

### DETAILED DESCRIPTION

Hereinafter, a thermoelectric device according to exemplary embodiments of the present disclosure will be described in detail with reference to the accompanying drawings.

In the disclosed drawings, width, length, and thickness of each component may not be to scale for the sake of convenience. Throughout the specification, like reference numerals refer to like elements.

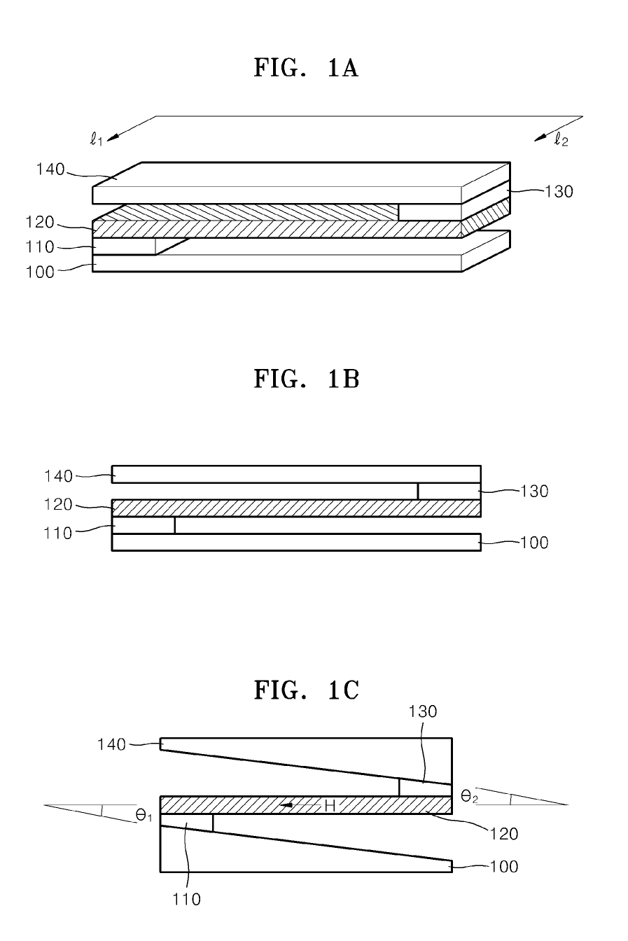

FIGS. 1A through 1C are views schematically illustrating a thermoelectric device according to an exemplary embodiment of the present disclosure. FIG. 1B shows a cross-section taken along a line l₁-l₂ of FIG. 1A.

Referring to FIGS. 1A and 1B, a thermoelectric object 120 is formed between a low-temperature region 100 and a high-temperature region 140. A first electrode 110 is formed between the low-temperature region 100 and the thermoelectric object 120, and a second electrode 130 is formed between the thermoelectric object 120 and the high-temperature region 140. The first electrode 110 is formed one an end of the top surface of the thermoelectric object 120 and the second electrode 130 is formed in another end of the bottom surface the thermoelectric object 120, such that the thermoelectric object 120 is spaced apart from the low-temperature region 100 and the high-temperature region 140.

The low-temperature region 100 and the high-temperature region 140 may be regions having different temperatures, and in the present exemplary embodiment, the high-temperature region 140 may have a higher temperature than the low-temperature region 100.

The low-temperature region 100 and the high-temperature region 140 may be formed of a flexible or non-flexible material such as silicon, gallium arsenide (GaAs), sapphire, quartz, glass, or polyimide.

The thermoelectric object 120 is a path along which heat or carriers (electrons, holes, or ions) move due to a temperature difference between the low-temperature region 100 and the high-temperature region 140. Referring to FIGS. 1B and 1C, a direction of heat H or carriers moving in the thermoelectric object 120 may be substantially parallel (FIG. 1B) or at an angle (FIG. 1C) with a facing surface of the low-temperature region 100. The thermoelectric object 120 may be substantially parallel (FIG. 1B) or at an angle (FIG. 1C) with a facing surface of the high-temperature region 140 and may be perpendicular to a shortest line connecting the low-temperature region 100 and the high-temperature region 140.

Herein, the facing surface of the low-temperature region 100 and the facing surface of the high-temperature region 140 indicate a surface of the low-temperature region 100 which faces the thermoelectric object 120 and a surface of the high-temperature region 140 which faces the thermoelectric object 120, respectively. In FIG. 1C, there is an angle θ₁ formed between a direction of heat H or carriers moving in the thermoelectric object 120 and the facing surface of the low-temperature region 100 and an angle θ₂ formed between the direction of heat H or carriers moving in the thermoelectric object 120 and the facing surface of the high-temperature region 140, where the angles θ₁ and θ₂ may be less than about 45 degrees. If the facing surface of the low-temperature region 100 and the facing surface of the high-temperature region 140 are curved surfaces, surfaces of the low-temperature region 100 and the high-temperature region 140 where the first electrode 110 and the second electrode 130 are formed, respectively, may be used as the facing surfaces of the low-temperature region 100 and the high-temperature region 140, such that the angle θ₁ or θ₂ between the direction of heat H or carriers moving and the low-temperature region 100 or between the direction of heat H or carriers moving and the high-temperature region 140 may be determined.

The thermoelectric object 120 may be made of various thermoelectric materials. For example, the thermoelectric object 120 may be formed of metal, intermetallic compounds, semiconductors, boride, oxide, or the like, and more specifically, may include BiTe compounds, PbTe compounds, SiGe compounds, and the like. The thermoelectric object 120 may be formed of an N-type material or a P-type material. For example, the thermoelectric object 120 may include group IV materials and group V materials or group IV materials and group III materials, or may be doped with an N-type or P-type dopant.

The first electrode 110 and the second electrode 130 may use any electrode material used in a general thermoelectric device, and may be formed of, for example, metal such as gold (Au), antigen (Ag), aluminium (Al), nickel (Ni), titanium (Ti), or platinum (Pt), or conductive metal oxide.

The thermoelectric object 120 is formed as a single structure between the low-temperature region 100 and the high-temperature region 140 of the thermoelectric device in FIGS. 1A through 1C, but the present disclosure is not limited thereto, and a plurality of thermoelectric objects 120 may also be formed.

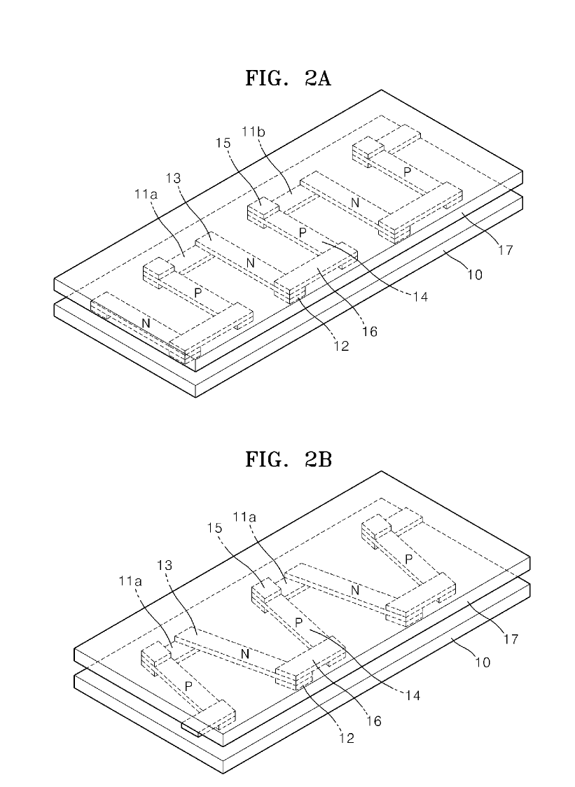

FIGS. 2A and 2B are views illustrating a thermoelectric device array according to an exemplary embodiment of the present disclosure. Herein, a plurality of thermoelectric objects 13 and 14 are formed between a low-temperature region 10 and a high-temperature region 17.

Referring to FIGS. 2A and 2B, a plurality of first electrodes 11a and 11b are formed on a surface of the low-temperature region 10 and a plurality of second electrodes 16 are formed on a surface of the high-temperature region 17. The first electrodes 11a and 11b and the second electrodes 16 are connected by thermoelectric objects 13 and 14. The thermoelectric objects 13 and 14 may be formed on ends of respective electrodes. That is, ends of the first electrodes 11a and 11b formed on the low-temperature region 10 and ends of the second electrodes 16 formed on the high-temperature region 17 are reciprocally connected in turns by the thermoelectric objects 13 and 14, thus forming a zig-zag structure. The thermoelectric objects 13 and 14 are parallel to each other in FIG. 2A, and the thermoelectric objects 13 and 14 are not parallel to each other in FIG. 2B.

The thermoelectric objects 13 and 14 may be formed of an N-type or P-type material and the thermoelectric object 13 of an N-type and the thermoelectric object 14 of a P-type may be formed in turns between the first electrode 11a and the second electrode 16 and between the first electrode 11b and the second electrode 16.

Ends of the thermoelectric objects 13 and 14 may be connected with the low-temperature region 10 through the first electrodes 11a and 11b, and the other ends of the thermoelectric objects 13 and 14 may be connected with the high-temperature region 17 through the second electrodes 16. Insulating layers 12 may be formed between ends of the thermoelectric objects 13 and the low-temperature region 10 and insulating layers 15 may be formed between ends of the thermoelectric objects 14 and the high-temperature region 17. For example, the N-type thermoelectric objects 13 are spaced apart from the low-temperature region 10, the first electrodes 11a are formed between the low-temperature region 10 and the ends of the N-type thermoelectric objects 13, and the insulating layers 12 are formed between the low-temperature region 10 and the ends of the N-type thermoelectric objects 13. The P-type thermoelectric objects 14 are spaced apart from the high-temperature region 17, the second electrodes 16 are formed between the high-temperature region 17 and the other ends of the P-type thermoelectric object 14, and the insulating layers 15 are formed between the high-temperature region 17 and the ends of the P-type thermoelectric objects 14.

The insulating layers 12 and 15 may be formed of an insulating material such as oxide, nitride, an organic material, or the like. When a thermoelectric device is formed, the insulating layers 12 and 15 may support the thermoelectric objects 13 and 14 such that the thermoelectric objects 13 and 14 do not directly contact the low-temperature region 10 or the high-temperature region 17. The insulating layers 12 and 15 may be formed of a material having a low heat conductivity to prevent heat from being delivered to the insulating layers 12 and 15.

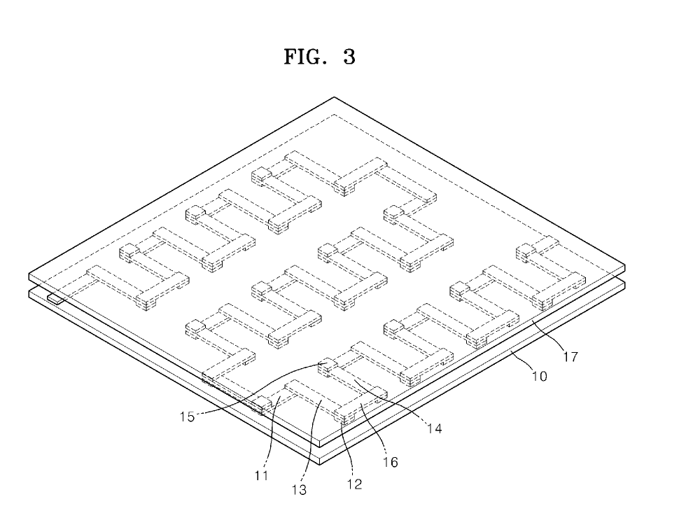

FIG. 3 is a view illustrating a thermoelectric module according to an exemplary embodiment of the present disclosure. As shown in FIG. 3, a plurality of patterns of first electrodes 11 and second electrodes 16 and the thermoelectric objects 13 and 14 between the first electrodes 11 and the second electrodes 16 are formed between the low-temperature region 10 and the high-temperature region 17. Carriers generated in the thermoelectric objects 13 and 14 may be connected with the outside of the thermoelectric module through the first and second electrodes 11 and 16.

The thermoelectric module according to the present exemplary embodiment of the present disclosure may be connected to a heat supply source and the first and second electrodes 11 and 16 of the thermoelectric module may be connected with an external electronic device, for example, a power consuming device or a power storing device.

Hereinafter, a description will be made of cases where in a thermoelectric device, a heat- or carrier-moving direction in a thermoelectric object is perpendicular and parallel between a low-temperature region and a high-temperature region.

A thermal resistance in a thermoelectric device may include a thermal resistance R_{TEG} in a thermoelectric object, a contact thermal resistance R between the thermoelectric object and a low-temperature region, and a contact thermal resistance R between the thermoelectric object and a high-temperature region. Herein, the contact thermal resistance R between the thermoelectric object and the low-temperature region and the contact thermal resistance R between the thermoelectric object and the high-temperature region are assumed to be the same. A temperature gradient of the thermoelectric device may include a temperature difference ΔT_{TOTAL} between the high-temperature region and the low-temperature region and a temperature difference ΔT_{TEG} between both ends of the thermoelectric object. If there is a temperature difference ΔT_{TOTAL} between the high-temperature region and the low-temperature region, the temperature difference ΔT_{TEG} between both ends of the thermoelectric object may be given by:

ΔT_{TEG}=(ΔT_{TOTAL}×R_{TEG})/(2R+R_{TEG})

As can be seen from this equation, as the contact thermal resistance R decreases and the thermal resistance R_{TEG} in the thermoelectric object increases, the temperature difference ΔT_{TEG} between both ends of the thermoelectric object increases, leading to an increase in the power generation efficiency of the thermoelectric device.

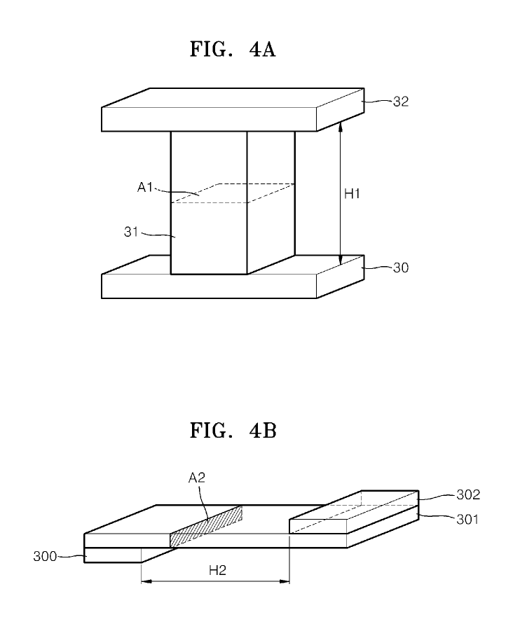

In the thermoelectric device according to an exemplary embodiment of the present disclosure, the direction of heat H or carriers moving in the thermoelectric object is substantially parallel with the facing surfaces of the low-temperature region and the high-temperature region, thereby increasing the thermal resistance (R_{TEG}) in the thermoelectric object, reducing the contact thermal resistance R between the thermoelectric object and the electrode, and providing superior performance, as will be described in more detail with reference to FIGS. 4A and 4B.

FIG. 4A is a view illustrating a thermoelectric device including a thermoelectric object 31 formed perpendicular to facing surfaces of a high-temperature region 32 and a low-temperature region 30. Referring to FIG. 4A, the thermoelectric object 31 is formed between the low-temperature region 30 and the high-temperature region 32.

Generally, a thermal resistance in a thermoelectric object, which connects a low-temperature region and a high-temperature region, is proportional to a length of the thermoelectric object, and is inversely proportional to a cross section of the thermoelectric object. Thus, in FIG. 4A, as a cross section A1 of the thermoelectric object 31 decreases and a length H1 of the thermoelectric object 31 increases, a thermal resistance in the thermoelectric object 31 increases and thus the performance efficiency of something decreases. As the cross section A1 of the thermoelectric object 31 decreases, a thermal resistance in the thermoelectric object 31 increases, and a contact thermal resistance between the thermoelectric object 31 and the low-temperature region 30 and a contact thermal resistance between the thermoelectric object 31 and the high-temperature region 32 also increase.

Since a thermoelectric device generates carriers by a temperature difference between the low-temperature region 30 and the high-temperature region 32, it is difficult to obtain a sufficient temperature gradient in the thermoelectric object 31 in case of high contact thermal resistance. The cross section A1 and length H1 of the thermoelectric object 31 may be determined according to a manufacturing process. As a ratio of the length H1 to the cross section A1, that is, H1/A1, increases, the manufacturing process is known to become more complicated. As a result, the structure shown in FIG. 4A has a limitation in increasing a thermal resistance of a thermoelectric object.

In a general thermoelectric device array, a plurality of thermoelectric devices are arranged between a low-temperature region and a high-temperature region which are two substrates, and thus it is not easy to increase the length H1 of the thermoelectric object 31. As a result, when the direction of heat H or carriers moving in the thermoelectric object 31 is perpendicular to facing surfaces of the low-temperature region 30 and the high-temperature region 32, there is a limitation in increasing the thermal resistance of the thermoelectric object 31.

FIG. 4B is a view illustrating a thermoelectric device including a thermoelectric object 301 formed in parallel with facing surfaces of a low-temperature region 300 and a high-temperature region 302. Referring to FIG. 4B, the thermoelectric object 301 is formed between the low-temperature region 300 and the high-temperature region 302.

A cross section A2 of the thermoelectric object 301 is changeable by two factors, that is, the thickness and width of the thermoelectric object 301. Therefore, the cross-section A2 of the thermoelectric object 301 may be reduced by a large amount by controlling the two factors. The cross section A2 of the thermoelectric object 301 may be changed independently of a contact area between the thermoelectric object 301 and the low-temperature region 300 and a contact area between the thermoelectric object 301 and the high-temperature region 302. The cross section A2 of the thermoelectric object 301 may also be reduced while increasing the contact areas.

Unlike in FIG. 4A where the length H1 of the thermoelectric object 31 is determined by a processable thickness, in FIG. 4B, a length H2 of the thermoelectric object 301 may be easily changed using a photomask, regardless of a processable thickness. Therefore, in FIG. 4B, the length H2 and cross section A2 of the thermoelectric object 301, which determine the thermal resistance of the thermoelectric object 301, may be designed independently of each other, and thus a ratio of the length H2 to the cross section A2, H2/A2, may be large.

Consequently, the thermoelectric device shown in FIG. 4B may easily improve power generation efficiency, compared to the thermoelectric device shown in FIG. 4A.

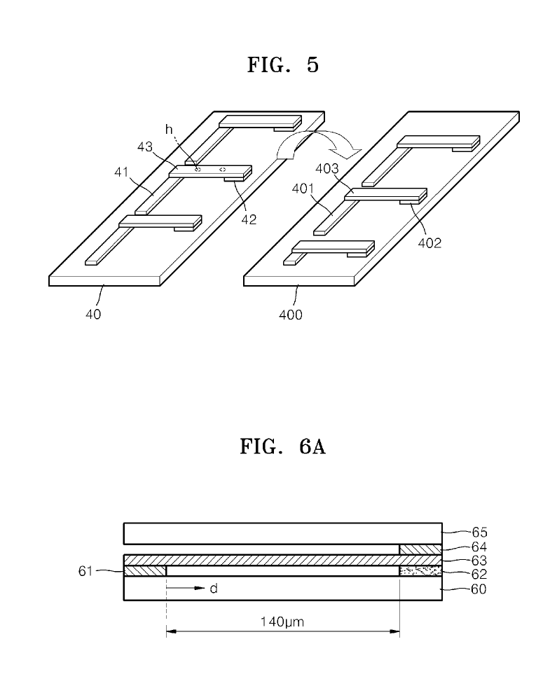

A thermoelectric device according to an exemplary embodiment of the present disclosure may be formed in various ways, and has no limitation in a size thereof. FIG. 5 is a view for describing a method of forming the thermoelectric device array shown in FIG. 2A, according to an exemplary embodiment of the present disclosure.

Referring to FIG. 5, first electrodes 41 and insulating layers 42 are formed in predetermined regions on a first substrate 40. The first electrodes 41 and the insulating layers 42 may be formed to have the same height. A sacrificial layer (not shown) is formed on the first substrate 40 and is planarized to the same height as the first electrodes 41 and the insulating layers 42, after which thermoelectric objects 43 are formed. The thermoelectric objects 43 are patterned to connect to ends of the first electrodes 41 and the insulating layers 42. Thereafter, upon removal of the sacrificial layer through an etching process, the first substrate 40 and the thermoelectric objects 43 may be spaced apart by a predetermined interval. For rapid etching of the sacrificial layer existing under the thermoelectric objects 43, etch holes h may be formed in the thermoelectric objects 43.

For a second substrate 400, the same process as for the first substrate 40 may be used to form second electrodes 401, insulating layers 402, and thermoelectric objects 403. By bonding the first substrate 40 and the second substrate 400, the thermoelectric device array shown in FIG. 2A may be formed.

In such a process, forming the thermoelectric objects 43 on the first substrate 40 with an N-type material and forming the thermoelectric objects 403 on the second substrate 400 with a P-type material may be separately performed. In this case, the thermoelectric device may be more easily manufactured than an existing perpendicular-type thermoelectric device where N-type thermoelectric objects and P-type thermoelectric objects have to be formed in turns on a single substrate. When thermoelectric objects are formed perpendicular to facing surfaces of two substrates, it is not easy to apply high pressure during a process of bonding the two substrates. In FIG. 5, however, a high pressure may be applied, thus reducing an electric resistance or a contact thermal resistance generated on the bonding surfaces.

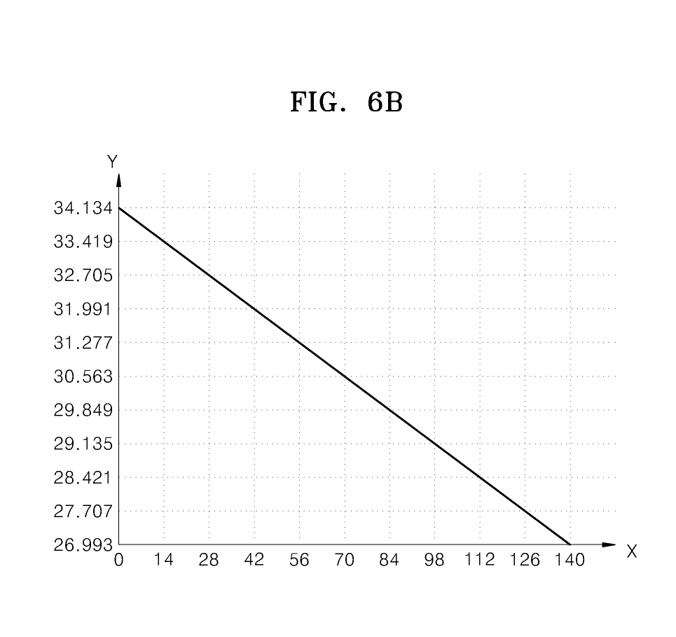

FIG. 6A is a view illustrating a thermoelectric device according to an exemplary embodiment of the present disclosure, and FIG. 6B is a graph showing the result of analyzing a temperature distribution in a thermoelectric object 63 of the thermoelectric device shown in FIG. 6A by using a numerical analysis program.

Referring to FIG. 6A, the thermoelectric object 63 is formed between the high-temperature region 60 and the low-temperature region 65 in parallel with facing surfaces of a high-temperature region 60 and a low-temperature region 65. A first electrode 61 and an insulating layer 62 are formed between the thermoelectric object 63 and the high-temperature region 60, and a second electrode 64 is formed between the low-temperature region 65 and the thermoelectric object 63 in a region where the insulating layer 62 is formed.

Herein, the thickness of the thermoelectric object 63 is about 2 μm and a length of a region where a temperature gradient is generated in the thermoelectric object 63 is about 140 μm. The high-temperature region 60 and the low-temperature region 65 are formed using a silicon wafer, and their thicknesses are about 300 μm. It is assumed that an interval between the thermoelectric object 63 and the high-temperature region 60 or the low-temperature region 65 is 2 μm, a temperature of the high-temperature region 60 is about 35° C., and a temperature of the low-temperature region 65 is about 25° C. A convective heat transfer coefficient of about 100 W/m²K has been used. Copper (Cu) has been used as materials of the first electrode 61 and the second electrode 64, and silicon dioxide (SiO₂) has been used for the insulating layer 62. Poly-silicon germanium (SiGe) has been used for the thermoelectric object 63.

In a condition where a temperature difference between the high-temperature region 60 and the low-temperature region 65 is about 10° C., a temperature distribution of the thermoelectric object 63 has been analyzed in a longitudinal direction and the analysis result is shown in the graph of FIG. 6B. In FIG. 6B, an X-axis indicates a d-direction length of the thermoelectric object 63 and a Y-axis indicates a temperature in centigrade.

Referring to FIG. 6B, heat moves according to a temperature difference between the high-temperature region 60 and the low-temperature region 65. It can be seen that the temperature of a region of the thermoelectric object 63 bonded with the first electrode 61 was about 34.134° C., and the internal temperature of the thermoelectric object 63 linearly decreases towards the second electrode 64. The result shown in FIG. 6B proves that a temperature gradient in the thermoelectric object 63 due to a temperature difference between the high-temperature region 60 and the low-temperature region 65 is generated in a longitudinal direction, that is, in parallel with facing surfaces of the high-temperature region 60 and the low-temperature region 65.

It is also seen that the amount of heat transferred from the high-temperature region 60 to the low-temperature region 65 through the insulating layer 62 is small and convective heat transfer in an empty space between the thermoelectric object 63 and the high-temperature region 60 and an empty space between the thermoelectric object 63 and the low-temperature region 65 is limited.

According to an exemplary embodiment of the present disclosure, by directing a direction of heat H or carriers moving in a thermoelectric object of a thermoelectric device substantially in parallel with facing surfaces of a high-temperature region and a low-temperature region, a heat resistance in the thermoelectric object can be increased. A contact heat resistance can be reduced by a large contact area between the thermoelectric object and an electrode, thereby improving power generation efficiency.

While many matters have been described above in detail, they should be interpreted as examples of an embodiment rather than limitations of the scope of the present disclosure. Accordingly, the scope of the present disclosure should be defined by the technical spirit of appended claims, rather than the foregoing embodiment.

What is claimed is:

1. A thermoelectric device comprising:
a low-temperature region;
a high-temperature region; and
a thermoelectric object disposed between the low-temperature region and the high-temperature region,
wherein a direction of heat or carriers moving in the thermoelectric object is substantially parallel or less than about 45 degrees with facing surfaces of the low-temperature region and the high-temperature region.

2. The thermoelectric device of claim 1, wherein an angle between the direction of heat or carriers moving in the thermoelectric object and the facing surface of the low-temperature region and an angle between the direction of heat or carriers moving in the thermoelectric object and the facing surface of the high-temperature region are less than about 45 degrees.

3. The thermoelectric device of claim 1, wherein the thermoelectric object is spaced apart from the low-temperature region and the high-temperature region, and comprises:
a first electrode disposed between an end of the thermoelectric object and the low-temperature region; and
a second electrode disposed between another end of the thermoelectric object and the high-temperature region.

4. The thermoelectric device of claim 3, further comprising an insulating layer disposed between the end of the thermoelectric object and the low-temperature region or between the other end of the thermoelectric object and the high-temperature region.

5. The thermoelectric device of claim 3, wherein the facing surfaces are surfaces on which the first electrode or the second electrode is disposed.

6. The thermoelectric device of claim 1, wherein the thermoelectric object is disposed in a direction substantially perpendicular to a shortest line connecting the low-temperature region and the high-temperature region.

7. The thermoelectric device of claim 1, wherein the thermoelectric object comprises metal, intermetallic compounds, semiconductors, boride, or oxide.

8. The thermoelectric device of claim 7, wherein the thermoelectric object comprises an N-type material or a P-type material.

9. A thermoelectric device array comprising:
a plurality of first electrodes disposed on a low-temperature region;
a plurality of second electrodes disposed on a high-temperature region;
thermoelectric objects spaced apart from the low-temperature region and the high-temperature region and formed by connecting ends of the plurality of first electrodes and ends of the plurality of second electrodes,
wherein directions of heat or carriers moving in the thermoelectric objects are substantially parallel or less than about 45 degrees with facing surfaces of the low-temperature region and the high-temperature region.

10. The thermoelectric device array of claim 9, wherein angles between the directions of heat or carriers moving in the thermoelectric objects and the facing surface of the low-temperature region and angles between the directions of heat or carriers moving in the thermoelectric objects and facing surface of the high-temperature region are less than about 45 degrees.

11. The thermoelectric device array of claim 9, wherein the facing surfaces are surfaces on which the first electrode or the second electrode is disposed.

12. The thermoelectric device array of claim 9, wherein the thermoelectric objects are disposed in a direction substantially perpendicular to a shortest line connecting the low-temperature region and the high-temperature region.

13. The thermoelectric device array of claim 9, wherein the ends of the plurality of first electrodes and the ends of the plurality of second electrodes are reciprocally connected in turns by the thermoelectric objects to form a zig-zag structure.

14. The thermoelectric device array of claim 13, wherein the thermoelectric objects are formed such that an N-type thermoelectric object and a P-type thermoelectric object are formed in turns.

15. The thermoelectric device array of claim 9, wherein the thermoelectric objects comprise metal, intermetallic compounds, semiconductors, boride, or oxide.

16. The thermoelectric device array of claim 15, wherein the thermoelectric objects comprise an N-type material or a P-type material.

17. The thermoelectric device array of claim 9, further comprising insulating layers formed between ends of the thermoelectric objects or other ends of the thermoelectric objects and the low-temperature region or the high-temperature region.
